(19) United States
(12) Patent Application Publication
(10) Pub. No.: US 2025/0228024 A1
(43) Pub. Date: Jul. 10, 2025

(54) SPECTRAL IMAGE SENSOR AND ELECTRONIC APPARATUS INCLUDING THE SAME

(71) Applicant: SAMSUNG ELECTRONICS CO., LTD., Suwon-si (KR)

(72) Inventors: Jaesoong LEE, Suwon-si (KR); Hyochul KIM, Suwon-si (KR); Youngho JUNG, Suwon-si (KR)

(73) Assignee: SAMSUNG ELECTRONICS CO., LTD., Suwon-si (KR)

(21) Appl. No.: 18/809,836

(22) Filed: Aug. 20, 2024

(30) Foreign Application Priority Data
Jan. 5, 2024 (KR) 10-2024-0002440

(51) Int. Cl. H01L 27/146

(52) U.S. Cl. CPC H10F 39/8053; H10F 39/8067; H10F 39/811

(57) ABSTRACT

A spectral image sensor includes a sensor substrate including a plurality of sensing elements, and a spectral filter provided on the sensor substrate, the spectral filter including a first unit filter configured to transmit light of a first central wavelength and a second unit filter configured to transmit light of a second central wavelength that is different from the first central wavelength, where the first unit filter and the second unit filter include a first reflective plate comprising a first distributed Bragg reflector (DBR), and a second reflective plate spaced apart from the first reflective plate, where the first unit filter includes a first resonant layer between the first reflective plate and the second reflective plate, and the second unit filter includes a second resonant layer between the first reflective plate and the second reflective plate.

### CROSS-REFERENCE TO RELATED APPLICATION

This application is based on and claims priority under 35 U.S.C. § 119 to Korean Patent Application No. 10-2024-0002440, filed on Jan. 5, 2024, in the Korean Intellectual Property Office, the disclosure of which is incorporated by reference herein in its entirety.

### BACKGROUND

### 1. Field

The disclosure relates to a spectral image sensor and an electronic device including the spectral image sensor.

### 2. Description of Related Art

In image sensors in the related art, a wavelength band may be divided into only three sections: red (R), green (G), and blue (B). However, in order to improve color expression accuracy and object recognition performance, there is a need for the development of a spectral image sensor having a spectral filter that divides a wavelength band into more sections. However, spectral filters in the related art have been used for dedicated cameras including bulky and complex optical element components, and spectral image sensor module technology for integrating a spectral filter on a semiconductor chip is still in the research and development stage.

### SUMMARY

Provided are a spectral image sensor and an electronic device including the same.

Additional aspects will be set forth in part in the description which follows and, in part, will be apparent from the description, or may be learned by practice of the presented embodiments of the disclosure.

According to an aspect of the disclosure, a spectral image sensor may include a sensor substrate including a plurality of sensing elements, and a spectral filter provided on the sensor substrate, the spectral filter including a first unit filter configured to transmit light of a first central wavelength and a second unit filter configured to transmit light of a second central wavelength that is different from the first central wavelength, where the first unit filter and the second unit filter include a first reflective plate comprising a first distributed Bragg reflector (DBR), and a second reflective plate spaced apart from the first reflective plate, where the first unit filter includes a first resonant layer between the first reflective plate and the second reflective plate, the second unit filter includes a second resonant layer between the first reflective plate and the second reflective plate, the first DBR includes a first reflective layer contacting the first resonant layer and having a first effective refractive index, and the first DBR includes a second reflective layer contacting the second resonant layer and having a second effective refractive index that is different from the first effective refractive index.

The first resonant layer may be configured to have a central wavelength within a green light wavelength range, and the second resonant layer may be configured to have a central wavelength within a red light wavelength range.

The first resonant layer may be configured to have a central wavelength within a green light wavelength range and the second resonant layer may be configured to have a central wavelength within a blue light wavelength range.

The first reflective layer may include a first material, and the second reflective layer may include the first material and a second material arranged in an alternating pattern, the second material having a refractive index that is different from a refractive index of the first material.

The first material may include titanium dioxide (TiO₂) and the second material may include silicon dioxide (SiO₂).

The first material may include titanium dioxide (TiO₂), and the second material may include silicon (Si).

The first reflective layer may include a first material, and the second reflective layer may include a second material having a refractive index that is different from a refractive index of the first material.

The second reflective plate may include a second DBR.

The second DBR may include a third reflective layer contacting the first resonant layer and a fourth reflective layer contacting the second resonant layer, and the fourth reflective layer has a fourth effective refractive index that is different from a third effective refractive index of the third reflective layer.

The second reflective plate may include a metal reflective plate.

The metal reflective plate may include aluminum (Al), copper (Cu), silver (Ag), gold (Au), titanium (Ti), tungsten (W), or titanium nitride (TiN).

The first resonant layer may have an effective refractive index that is different from a refractive index of the second resonant layer.

A thickness of the first resonant layer may be substantially the same as a thickness of the second resonant layer.

The first unit filter may include a first bandpass filter corresponding to the first resonant layer, and the second unit filter may include a second bandpass filter corresponding to the second resonant layer.

The first bandpass filter may be configured to transmit light of a first wavelength range, and the second bandpass filter may be configured to transmit light of a second wavelength range.

The first central wavelength may be within the first wavelength range, and the second resonant layer may be configured to have a central wavelength within the second wavelength range.

Each of the plurality of sensing elements may include a wiring layer comprising a driving circuit and a photodiode on the wiring layer.

The spectral image sensor may include a timing controller, a row decoder, and an output circuit.

According to an aspect of the disclosure, an electronic device including a spectral image sensor including a sensor substrate including a plurality of sensing elements, and a spectral filter provided on the sensor substrate, the spectral filter including a first unit filter configured to transmit light of a first central wavelength and a second unit filter configured to transmit light of a second central wavelength that is different from the first central wavelength, where the first unit filter and the second unit filter include a first reflective plate comprising a first DBR, and a second reflective plate spaced apart from the first reflective plate, where the first unit filter includes a first resonant layer between the first reflective plate and the second reflective plate, the second unit filter includes a second resonant layer between the first reflective plate and the second reflective plate, the first DBR includes a first reflective layer contacting the first resonant layer and having a first effective refractive index, and the first DBR includes a second reflective layer contacting the second resonant layer and having a second effective refractive index that is different from the first effective refractive index.

The electronic device may include a mobile phone, a smartphone, a tablet, a smart tablet, a digital camera, a camcorder, a laptop computer, a television, a smart television, a smart refrigerator, a security camera, a robot, or a medical camera.

According to an aspect of the disclosure, a spectral image sensor may include a sensor substrate including a plurality of sensing elements, and a spectral filter provided on the sensor substrate, the spectral filter including a first unit filter configured to transmit light of a first central wavelength, a second unit filter configured to transmit light of a second central wavelength that is different from the first central wavelength, and a third unit filter configured to transmit light of a third central wavelength that is different from the first central wavelength and the second central wavelength, where the first unit filter, the second unit filter and the third unit filter include a first reflective plate including a first DBR and a second reflective plate spaced apart from the first reflective plate, where the first unit filter includes a first resonant layer between the first reflective plate and the second reflective plate, the second unit filter includes a second resonant layer between the first reflective plate and the second reflective plate, and the third unit filter includes a third resonant layer between the first reflective plate and the second reflective plate.

The first DBR may include a first reflective layer contacting the first resonant layer and having a first effective refractive index, a second reflective layer contacting the second resonant layer and having a second effective refractive index that is different from the first effective refractive index, and a third reflective layer contacting the third resonant layer and having a third effective refractive index that is different from the first effective refractive index and the second effective refractive index.

The first reflective layer may include a first material and a second material arranged in an alternating pattern, and the second material may have a refractive index that is different from a refractive index of the first material.

The second reflective layer may include only the first material.

The third reflective layer may include the first material and a third material arranged in an alternating pattern, and the third material may have a refractive index that is different from the refractive index of the first material.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a cross-sectional view illustrating a spectral image sensor according to one or more embodiments;

FIG. 2 is a block diagram illustrating a spectral image sensor according to one or more embodiments;

FIG. 3 is a diagram illustrating an example of a plane of a spectral filter array shown in FIG. 2 according to one or more embodiments;

FIG. 4 is a cross-sectional view illustrating a spectral filter according to one or more embodiments;

FIGS. 5A to 5C are diagrams illustrating examples of distributed Bragg reflective plates according to one or more embodiments;

FIGS. 6A to 6C are graphs illustrating reflection spectra of the examples of distributed Bragg reflective plates shown in FIGS. 5A to 5C according to one or more embodiments;

FIG. 7 is a cross-sectional view illustrating a spectral filter according to one or more embodiments;

FIG. 8 is a cross-sectional view illustrating a spectral filter according to one or more embodiments;

FIG. 9 is a cross-sectional view illustrating a spectral filter according to one or more embodiments;

FIG. 10 is a cross-sectional view illustrating a spectral filter according to one or more embodiments;

FIGS. 11A to 11C are graphs illustrating examples of transmission spectra of first, second, and third band-pass filters in the spectral filter shown in FIG. 10 according to one or more embodiments;

FIGS. 12A to 12C are graphs illustrating examples of transmission spectra of first, second, and third resonant layers in the spectral filter shown in FIG. 10 according to one or more embodiments;

FIG. 13 is a block diagram illustrating an example of an electronic device according to one or more embodiments;

FIG. 14 is a block diagram illustrating an example of a camera module of FIG. 13 according to one or more embodiments; and

FIGS. 15A-15E to 16A-16E are diagrams illustrating various examples of an electronic device according to one or more embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

Hereinafter, example embodiments will be described in detail with reference to the accompanying drawings. The embodiments described below are merely exemplary, and various modifications are possible from these embodiments. In the following drawings, the same reference numerals refer to the same components, and the size of each component in the drawings may be exaggerated for clarity and convenience of description.

In the following description, when a component is referred to as being “above” or “on” another component, it may be directly on an upper, lower, left, or right side of the other component while making contact with the other component or may be above an upper, lower, left, or right side of the other component without making contact with the other component.

In addition, when a part is described to “comprise” or “include” a certain element, this means that the part may further include other elements, rather than excluding other elements, unless specifically described to the contrary.

The use of the term “the” and similar designating terms may correspond to both the singular and the plural. Terms such as first, second, etc. may be used to describe various components, but are used only for the purpose of distinguishing one component from another component. These terms do not limit the difference in the material or structure of the components.

Operations of a method may be performed in an appropriate order unless explicitly described in terms of order. In addition, the use of all illustrative terms (e.g., etc.) is merely for describing technical ideas in detail, and the scope is not limited by these examples or illustrative terms unless limited by the claims.

In addition, terms such as “unit” and “module” described in the specification may indicate a unit that processes at least one function or operation, and this may be implemented as hardware or software, or may be implemented as a combination of hardware and software.

The connections or connection members of lines between elements shown in the drawings show examples of functional connections and/or physical or circuit connections and, in actual devices, may be shown as various functional connections, physical connections, or circuit connections that are replaceable or added.

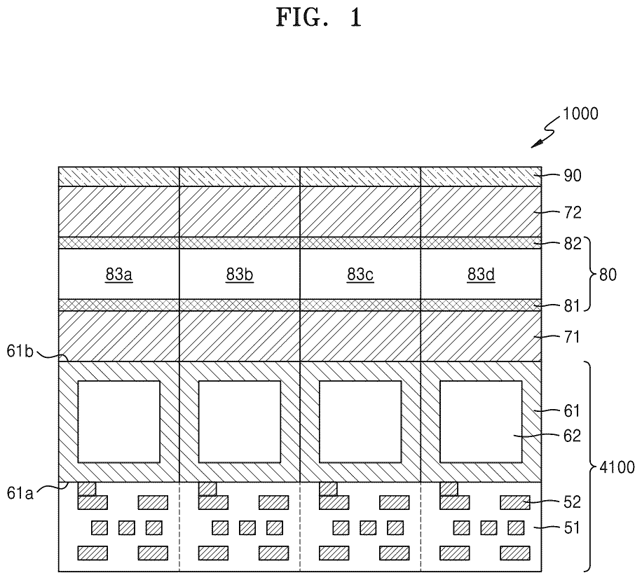

FIG. 1 is a cross-sectional view illustrating a spectral image sensor 1000 according to one or more embodiments. The spectral image sensor 1000 shown in FIG. 1 may include, for example, a complementary metal oxide semiconductor (CMOS) image sensor or a charge coupled device (CCD) image sensor.

Referring to FIG. 1, the spectral image sensor 1000 may include a sensor substrate 4100 and a resonator structure 80 that is provided on the sensor substrate 4100. The sensor substrate 4100 may include a plurality of sensing elements that are two-dimensionally arranged, and the resonator structure 80 may include a plurality of resonators provided to correspond to the plurality of sensing elements. In FIG. 1, the sensor substrate 4100 includes four sensing elements, and the resonator structure 80 includes four resonators.

Each of the sensing elements of the sensor substrate 4100 may include a photodiode 62, which is a photoelectric conversion element, and a driving circuit 52 for driving that photodiode 62. The photodiode 62 may be provided in a semiconductor substrate 61. For example, a silicon substrate may be used for the semiconductor substrate 61. However, the disclosure is not limited thereto. A wiring layer 51 may be provided on a lower surface 61a of the semiconductor substrate 61, and the driving circuit 52, such as a metal-oxide-semiconductor (MOS) field-effect transistor (FET) (MOSFET), may be provided inside that wiring layer 51.

The resonator structure 80 including a plurality of resonators may be provided over the semiconductor substrate 61 above an upper surface 61b of the semiconductor substrate 61. Each of the resonators may be provided to transmit light of a predetermined wavelength range. Each of the resonators may include first and second reflective plates 81 and 82, which are spaced apart from each other, and resonant layers 83a, 83b, 83c, and 83d provided between the first reflective plate 81 and the second reflective plate 82. Each of the first and second reflective plates 81 and 82 may include, for example, a metal reflective plate or a Bragg reflective plate. Each of the resonant layers 83a, 83b, 83c, and 83d may be provided to resonate light in a certain desired wavelength range.

A first functional layer 71 may be provided between an upper surface of the semiconductor substrate 61 and the resonator structure 80. For example, the first functional layer 71 may improve transmittance of light passing through the resonator structure 80 and incident toward the photodiode 62. To this end, the first functional layer 71 may include a dielectric layer or dielectric pattern with an adjusted refractive index.

A second functional layer 72 may be provided on an upper surface of the resonator structure 80. For example, the second functional layer 72 may improve transmittance of light incident toward the resonator structure 80. To this end, the second functional layer 72 may include a dielectric layer or dielectric pattern with an adjusted refractive index. A third functional layer 90 may be further provided on an upper surface of the second functional layer 72. The third functional layer 90 may include, for example, an antireflection layer, a focusing lens, a color filter, a short-wavelength absorption filter, or a long-wavelength blocking filter. However, this is only an example.

At least one of the first, second, and third functional layers 71, 72, and 90 described above may constitute a spectral filter together with the resonator structure 80.

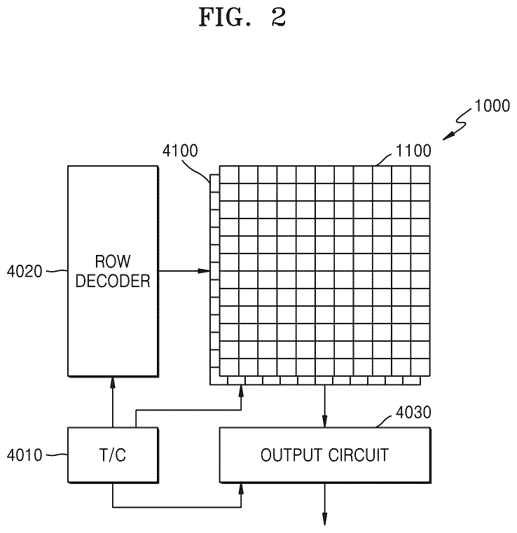

FIG. 2 is a block diagram illustrating a spectral image sensor 1000 according to one or more embodiments.

Referring to FIG. 2, the spectral image sensor 1000 may include a spectral filter array 1100, the sensor substrate 4100, a timing controller (T/C) 4010, a row decoder 4020, and an output circuit 4030.

As described below, the spectral filter array 1100 may include a plurality of spectral filters, and each of the plurality of spectral filters may include a plurality of unit filters configured to transmit light of different wavelengths from each other. The sensor substrate 4100 may include a plurality of sensing elements that detect light passing through the spectral filter array 1100. For example, the sensor substrate 4100 may include sensing elements that are two-dimensionally arranged along a plurality of rows and columns. The row decoder 4020 may select one of rows of the sensor substrate 4100 in response to a row address signal output from the T/C 4010. The output circuit 4030 may output a light-sensing signal in units of columns from a plurality of sensing elements arranged along the selected row. To this end, the output circuit 4030 may include a column decoder and an analog to digital converter (ADC). For example, the output circuit 4030 may include a plurality of ADCs arranged for each column between the column decoder and the sensor substrate 4100 or may include a single ADC arranged at an output terminal of the column decoder. The T/C 4010, the row decoder 4020, and the output circuit 4030 may be implemented as one chip or as separate chips. A processor for processing an image signal output through the output circuit 4030 may be implemented as a single chip together with the T/C 4010, the row decoder 4020, and the output circuit 4030.

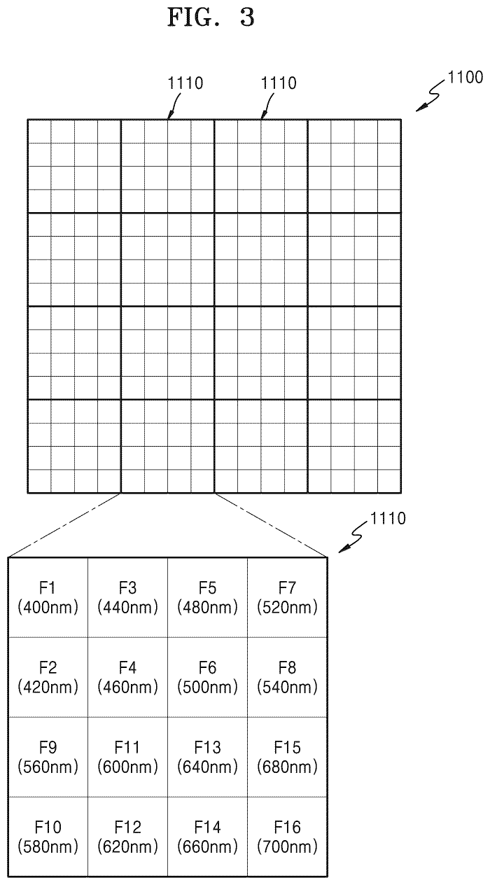

FIG. 3 is a diagram illustrating an example of a plane of a spectral filter array 1100 shown in FIG. 2 according to one or more embodiments.

Referring to FIG. 3, the spectral filter array 1100 may include a plurality of spectral filters 1110 that are two-dimensionally arranged. Here, for example, each of the spectral filters 1110 may include 16 unit filters F1 to F16 arranged in a 4×4 array.

In FIG. 3, the 16 unit filters F1 to F16 have central wavelengths in a visible light range between about 400 nm and about 700 nm. However, this is only an example. For example, the 16 unit filters F1 to F16 may have central wavelengths in the visible light range and in a near-infrared range.

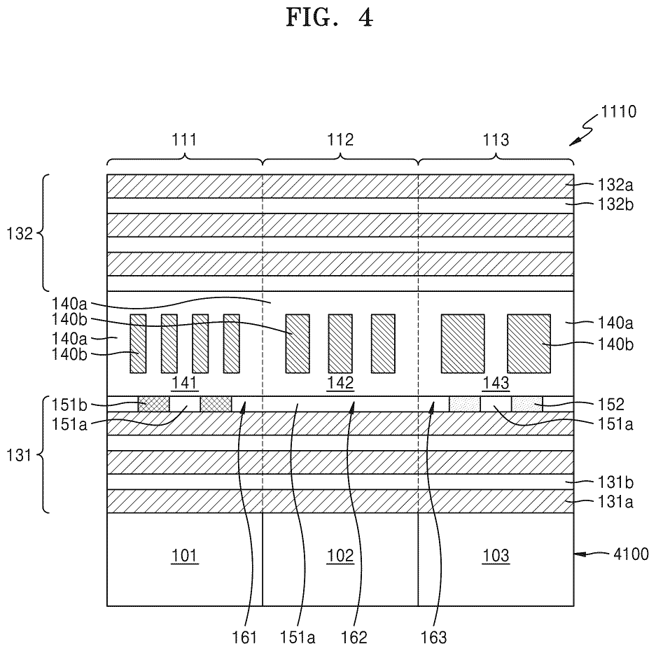

FIG. 4 is a cross-sectional view illustrating a spectral filter 1100 according to one or more embodiments.

Referring to FIG. 4, the spectral filter 1110 may include a plurality of unit filters 111, 112, and 113 configured to transmit light of different central wavelengths. In FIG. 4, for convenience, a first, second, and third unit filters 111, 112, and 113 are shown. The sensor substrate 4100 may be provided under the spectral filter 1110. The sensor substrate 4100 may include a plurality of sensing elements 101, 102, and 103 provided in one-to-one correspondence with the plurality of unit filters 111, 112, and 113. In FIG. 4, the first, second, and third sensing elements 101, 102, and 103 respectively corresponding to the first, second, and third unit filters 111, 112, and 113 are shown as an example, and more sensing elements and unit filters may be implemented.

The first, second, and third unit filters 111, 112, and 113 may transmit light of different central wavelengths from each other. For example, each of the first, second, and third unit filters 111, 112, and 113 may have central wavelengths in different wavelength bands in the visible light range (wavelength range of about 400 nm to about 700 nm). For example, the first unit filter 111 may have a central wavelength in a blue light band, the second unit filter 112 may have a central wavelength in a green light band, and the third unit filter 113 may have a central wavelength in a red light band. However, the disclosure is not limited thereto, and at least some of the first, second, and third unit filters 111, 112, and 113 may have a central wavelength in wavelength ranges (e.g., a near-infrared range) other than the visible light range.

The first, second, and third unit filters 111, 112, and 113 may include resonators of a Fabry-Perot structure. Each of the first, second, and third unit filters 111, 112, and 113 may include first and second reflective plates 131 and 132. For example, the first unit filter 111 may include the first and second reflective plates 131 and 132 and the first resonant layer 141 provided between the first and second reflective plates 131 and 132, the second unit filter 112 may include the first and second reflective plates 131 and 132 and the second resonant layer 142 provided between the first and second reflective plates 131 and 132, and the third unit filter 113 may include the first and second reflective plates 131 and 132 and the third resonant layer 143 provided between the first and second reflective plates 131 and 132. Here, as described below, each of the first and second reflective plates 131 and 132 may include a distributed Bragg reflector (DBR).

When external light passes through the first reflective plate 131 and is incident on the resonant layers 141, 142, and 143, this light may travel back and forth inside the resonant layers 141, 142, and 143 between the first and second reflective plates 131 and 132, causing constructive interference and destructive interference. In addition, light having a central wavelength that satisfies constructive interference conditions in the resonant layers 141, 142, and 143 may pass through the first reflective plate 131 and may be incident on each of the sensing elements 101, 102, and 103 of the sensor substrate 4100.

The first, second, and third unit filters 111, 112, and 113 may transmit light of different central wavelengths from each other. To this end, the first, second, and third resonant layers 141, 142, and 143 may have different central wavelengths. For example, the first resonant layer 141 may have a central wavelength in a blue light band, the second resonant layer 142 may have a central wavelength in a green light band, and the third resonant layer 143 may have a central wavelength in a red light band.

The first, second, and third resonant layers 141, 142, and 143 may be configured to have different effective refractive indices. To this end, each of the first, second, and third resonant layers 141, 142, and 143 may include at least one material layer. In FIG. 4, each of the first, second, and third resonant layers 141, 142, and 143 includes a first material layer 140a and a second material layer 140b having different refractive indices from each other. The second material layer 140b may be arranged inside the first material layer 140a to form a predetermined pattern. Here, a size or shape of the pattern formed by the second material layer 140b may be changed to adjust an effective refractive index of each of the first, second, and third resonant layers 141, 142, and 143. The first, second, and third resonant layers 141, 142, and 143 may have substantially the same thickness as each other. Each of the first and second material layers 140a and 140b may include, for example, silicon, silicon oxide, silicon nitride, titanium oxide, aluminum oxide, hafnium oxide, gallium phosphide (GaP), or the like. For example, the first material layer 140a may include silicon oxide, and the second material layer 140b may include titanium oxide having a higher refractive index than silicon oxide. In other embodiments, the space between the first reflective plate 131 and the second reflective plate 132 may exist as a vacuum cavity or a cavity filled with air, without requiring any additional material to occupy the space, to act as a resonant structure (including the first, second, and third resonant layers 141, 142, and 143).

The first reflective plate 131 may include a first DBR, and the second reflective plate 132 may include a second DBR. Each of the first and second DBRs may have a structure in which two or more dielectrics having different refractive indices from each other are alternately stacked. In FIG. 4, the first and second DBRs have a structure in which the first material layers 131a and 132a and the second material layer 131b and 132b having different indices from each other are alternately stacked, respectively. For example, the first material layers 131a and 132a may include silicon oxide, and the second material layer 131b and 132b may include titanium oxide having a higher refractive index than silicon oxide.

The first DBR may include first, second, and third reflective layers 161, 162, and 163 contacting the first, second, and third resonant layers 141, 142, and 143, respectively. For example, the first DBR of the first unit filter 111 may include the first reflective layer 161 contacting the first resonant layer 141, the first DBR of the second unit filter 112 may include the second reflective layer 162 contacting the second resonant layer 142, and the first DBR of the third unit filter 113 may include the third reflective layer 163 contacting the third resonant layer 143.

The first resonant layer 141 contacting the first resonant layer 141, the second reflective layer 162 contacting the second resonant layer 142, and the third reflective layer 163 contacting the third resonant layer 143 may have different effective refractive indices. To this end, the first, second, and third reflective layers 161, 162, and 163 may include materials having different refractive indices.

When the second resonant layer 142 has a central wavelength in the green light range, the second reflective layer 162 contacting the second resonant layer 142 may include a first material 151a. In some embodiments, the second reflective layer 162 may include only the first material 151a. The first material 151a may be, for example, one of materials included in the first DBR. For example, the second reflective layer 162 may include titanium oxide. However, this is only an example, and the second reflective layer 162 may include silicon oxide or other materials.

When the first resonant layer 141 has a central wavelength in the blue light range, the first reflective layer 161 contacting the first resonant layer 141 may be configured to have an effective refractive index different from that of the second reflective layer 162. For example, the first reflective layer 161 may include the first material 151a and a second material 151b. Here, the first material 151a may be, as described above, one of the materials included in the first DBR. In addition, the second material 151b, which has a refractive index different from that of the first material 151a, may be arranged with the first material 151a to form an alternating pattern. For example, the second material 151b may have a lower refractive index than the first material 151a. For example, the first reflective layer 161 may include titanium oxide and silicon oxide that is arranged in a predetermined pattern within that titanium oxide. However, this is only an example, and in some cases, the second material 151b may have a higher refractive index than the first material 151a. As described above, when the first reflective layer 161 contacting the first resonant layer 141 is configured to have an effective refractive index different from that of the second reflective layer 162, as described below, the reflectance in a particular wavelength range, for example, in the blue light range (in particular, a stop band), may be improved.

When the third resonant layer 143 has a central wavelength in the red light range, the third reflective layer 163 contacting third resonant layer 143 may be configured to have an effective refractive index different from those of the first and second reflective layers 161 and 162. For example, the third reflective layer 163 may include the first material 151a and a third material 152. The first material 151a may be, as described above, one of the materials included in the first DBR. In addition, the third material 152, which has a refractive index different from that of the second material 151b, may be arranged with the first material 151a to form an alternating pattern. For example, the third material 152 may have a higher refractive index than the first material 151a. For example, the third reflective layer 163 may include titanium oxide and silicon that is arranged in a predetermined pattern within that titanium oxide. However, this is only an example, and in some cases, the third material 152 may have a lower refractive index than the first material 151a. As described above, when the third reflective layer 163 in contacting the third resonant layer 143 is configured to have an effective refractive index different from those of the first and second reflective layers 161 and 162, as described below, the reflectance in a particular wavelength range, for example, in the red light range (in particular, a stop band), may be improved.

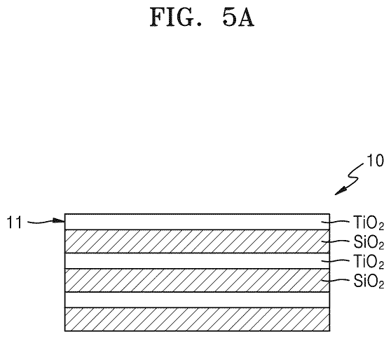

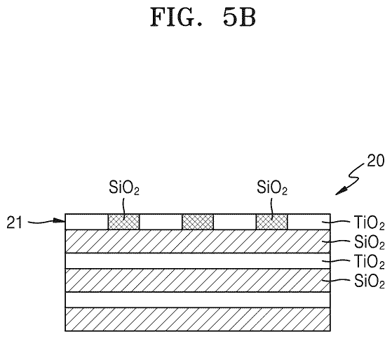

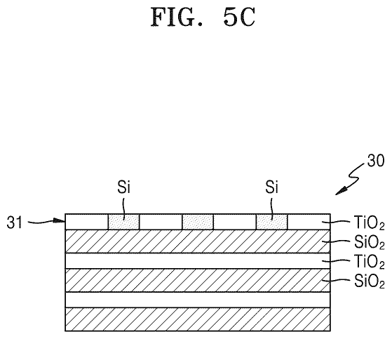

FIGS. 5A to 5C are diagrams illustrating examples of distributed Bragg reflective plates according to one or more embodiments. FIGS. 5A to 5C illustrate examples of DBRs 10, 20, and 30. The DBR 10 shown in FIG. 5A may have a general DBR in which silicon dioxide (SiO₂) and titanium dioxide (TiO₂) are alternately stacked. In the DBR 10 shown in FIG. 5A, a reflective layer 11 contacting a resonant layer may include TiO₂. The DBR 20 shown in FIG. 5B is similar to the DBR 10 shown in FIG. 5A except for a reflective layer 21 contacting a resonant layer. In the DBR 20 shown in FIG. 5B, the reflective layer 21 contacting the resonant layer may include TiO₂ and SiO₂, which is arranged in a predetermined pattern within that TiO₂ and has a lower refractive index than TiO₂. The DBR 30 shown in FIG. 5C is similar to the DBR 10 shown in FIG. 5A except for a reflective layer 31 contacting a resonant layer. In the DBR 30 shown in FIG. 5C, the reflective layer 31 contacting the resonant layer may include TiO₂ and silicon (Si), which is arranged in a predetermined pattern within that TiO₂ and has a higher refractive index than TiO₂.

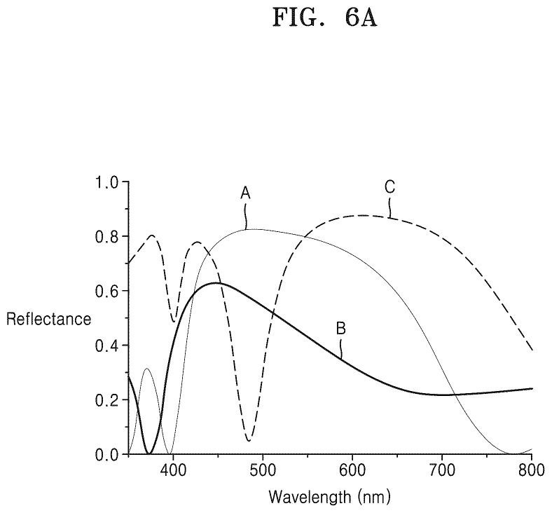

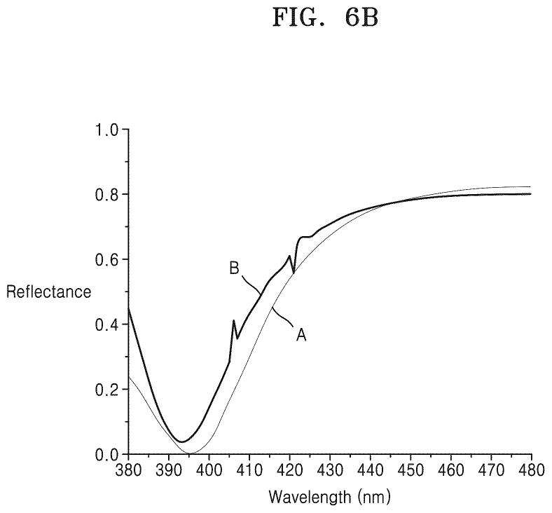

FIGS. 6A to 6C are graphs illustrating reflection spectra of the examples of distributed Bragg reflective plates shown in FIGS. 5A to 5C according to one or more embodiments. That is, FIGS. 6A to 6C illustrate reflection spectra of the examples of the DBRs 10, 20, and 30 shown in FIGS. 5A to 5C. FIG. 6B shows an enlarged view of the wavelength range of about 400 nm to about 480 nm, and FIG. 6C shows an enlarged view of the wavelength range of about 550 nm to about 800 nm.

In FIGS. 6A to 6C, “A” represents a reflection spectrum of the DBR 10 shown in FIG. 5A, “B” represents a reflection spectrum of the DBR 20 shown in FIG. 5B, and “C” represents a reflection spectrum of the DBR 30 shown in FIG. 5C.

Referring to FIGS. 6A and 6B, in the wavelength range of about 420 nm to about 430 nm, it may be seen that reflectance of the DBR 20 shown in FIG. 5B increased by approximately 10% or more compared to reflectance of the DBR 10 shown in FIG. 5A. In addition, referring to FIGS. 6A and 6C, in the wavelength range of about 550 nm to about 800 nm, it may be seen that reflectance of the DBR 30 shown in FIG. 5C increased by approximately 10% or more compared to reflectance of the DBR 10 shown in FIG. 5A.

According to one or more embodiments, in the first DBR of the second unit filter 112 having a central wavelength within the green light wavelength range, the second reflective layer 162 contacting the second resonant layer 142 may include a first material 151a (e.g., titanium oxide), which is one of materials included in the first DBR. In addition, in the first DBR of the first unit filter 111 having a central wavelength within the blue light wavelength range, the first reflective layer 161 contacting the first resonant layer 141 includes the first material 151a (e.g., titanium oxide) and a second material 151b (e.g., silicon oxide) having a refractive index different from that of the first material 151a, thereby improving reflectance in the blue light wavelength range. In addition, in the first DBR of the third unit filter 113 having a central wavelength within the red light wavelength range (or, near-infrared range), the third reflective layer 163 contacting the third resonant layer 143 includes the first material 151a (e.g., titanium oxide) and a third material 152 (e.g., silicon) having a refractive index different from that of the first material 151a, thereby improving reflectance in the red light wavelength range (or, near-infrared range). Accordingly, the spectral image sensor 1000 with improved spectral performance may be implemented. Materials of the reflective layers 161, 162, and 163 described above are only examples, and in addition to foreign substances, other materials (e.g., silicon nitride, aluminum oxide, hafnium oxide, GaP, or the like) may be used for the reflective layers.

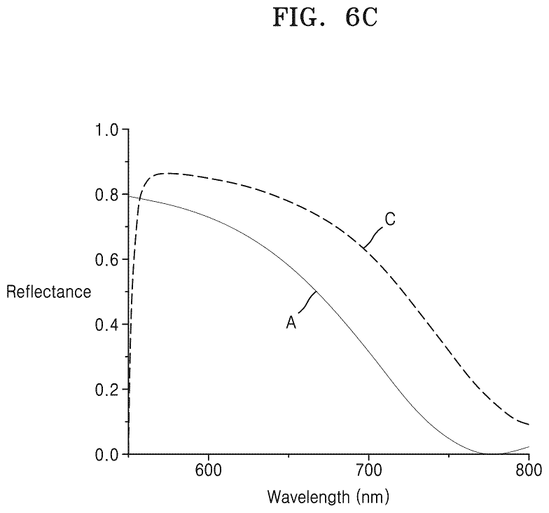

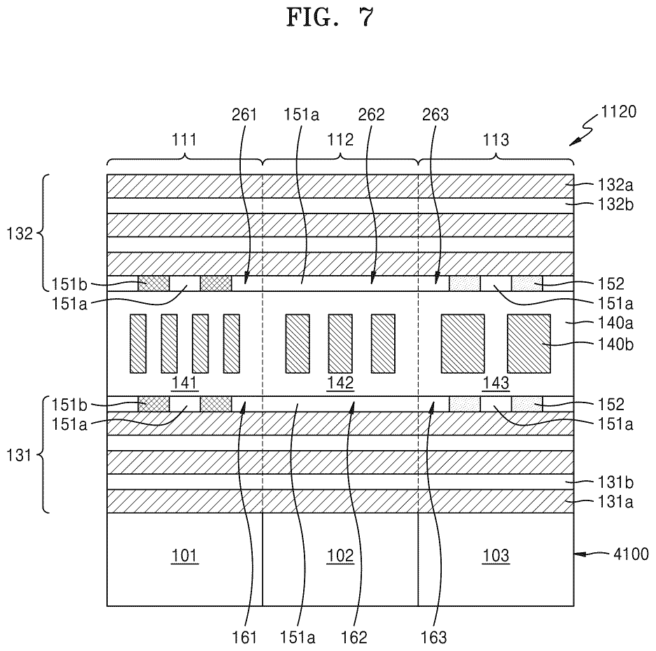

FIG. 7 is a cross-sectional view illustrating a spectral filter 1120 according to one or more embodiments. Hereinbelow, Differences from embodiments described above are mainly described.

Referring to FIG. 7, the first reflective plate 131 may include the first DBR, and the second reflective plate 132 may include the second DBR. Each of the first and second DBRs may have a structure in which two or more dielectrics having different refractive indices from each other are alternately stacked.

In the first DBR, the first reflective layer 161 contacting the first resonant layer 141, the second reflective layer 162 contacting the second resonant layer 142, and the third reflective layer 163 contacting the third resonant layer 143 may have different effective refractive indices. To this end, the first, second, and third reflective layers 161, 162, and 163 may include materials having different refractive indices. In the second DBR, a fourth reflective layer 261 contacting the first resonant layer 141, a fifth reflective layer 262 contacting the second resonant layer 142, and a sixth reflective layer 263 contacting the third resonant layer 143 may have different effective refractive indices. To this end, the fourth, fifth, and sixth reflective layers 261, 262, and 263 may include materials having different refractive indices from each other.

The second and fifth reflective layers 162 and 262 contacting the second resonant layer 142 may include the first material 151a. The first and fourth reflective layers 161 and 261 contacting the first resonant layer 141 may be configured to have effective refractive indices different from those of the second and fifth reflective layers 162 and 262. For example, the first and fourth reflective layers 161 and 261 may include first and second materials 151a and 151b, respectively. The third and sixth reflective layers 163 and 263 contacting the third resonant layer 143 may be configured to have effective refractive indices different from those of the second and fifth reflective layers 162 and 262. For example, the third and sixth reflective layers 163 and 263 may include the first material 151a and a third material 152, respectively.

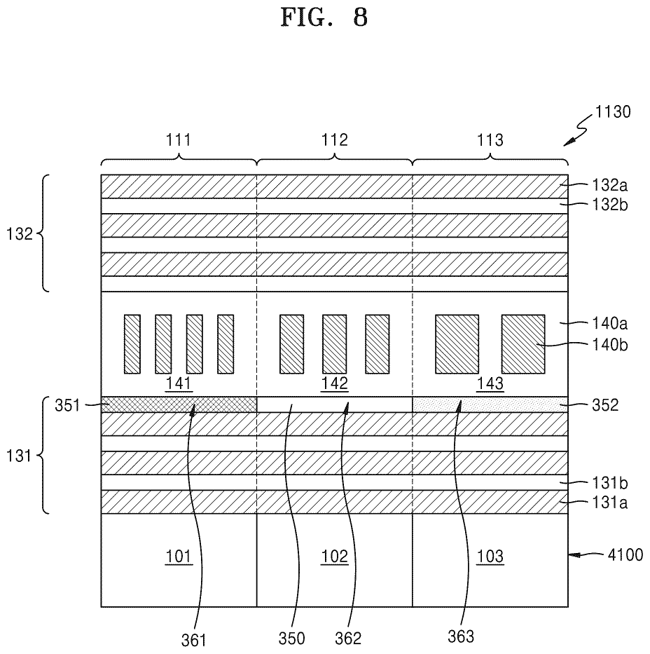

FIG. 8 is a cross-sectional view illustrating a spectral filter 1130 according to one or more embodiments. Differences from embodiments described above are mainly described.

Referring to FIG. 8, a first reflective layer 361 contacting the first resonant layer 141, a second reflective layer 362 contacting the second resonant layer 142, and a third reflective layer 363 contacting the third resonant layer 143 may have different effective refractive indices from each other. To this end, the first, second, and third reflective layers 361, 362, and 363 may include materials having different refractive indices.

When the second resonant layer 142 has a central wavelength in the green light range, the second reflective layer 362 contacting the second resonant layer 142 may include the first material 350. When the first resonant layer 141 has a central wavelength in the blue light range, the first reflective layer 361 contacting the first resonant layer 141 may be configured to have an effective refractive index different from that of the second reflective layer 362. For example, the first reflective layer 361 may include a second material 351 having a refractive index different from that of the first material 350. For example, the second material 351 may have a lower refractive index than the first material 350, but is not limited thereto. When the third resonant layer 143 has a central wavelength in the red light range, the third reflective layer 363 contacting the third resonant layer 143 may be configured to have an effective refractive index different from those of the first and second reflective layers 361 and 362. For example, the third reflective layer 363 may include a third material 352 having a refractive index different from that of the first material 350. For example, the third material 352 may have a higher refractive index than the first material 350, but is not limited thereto.

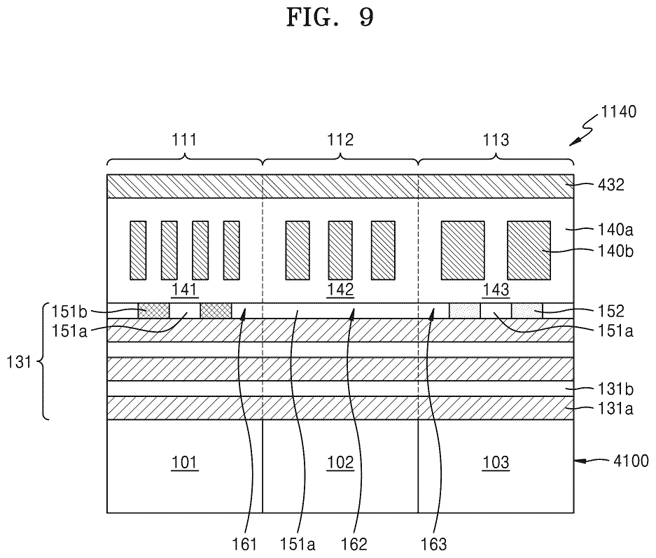

FIG. 9 is a cross-sectional view illustrating a spectral filter 1140 according to one or more embodiments. The spectral filter 1140 shown in FIG. 9 is similar to the spectral filter 1110 shown in FIG. 4, except that the spectral filter 1140 uses a metal reflective plate as a second reflective plate 432 instead of a DBR. Referring to FIG. 9, the second reflective plate 432 may include a metal reflective plate. This metal reflective plate may include, for example, aluminum (AI), copper (Cu), silver (Ag), gold (Au), titanium (Ti), tungsten (W), or titanium nitride (TiN). However, this is only an example.

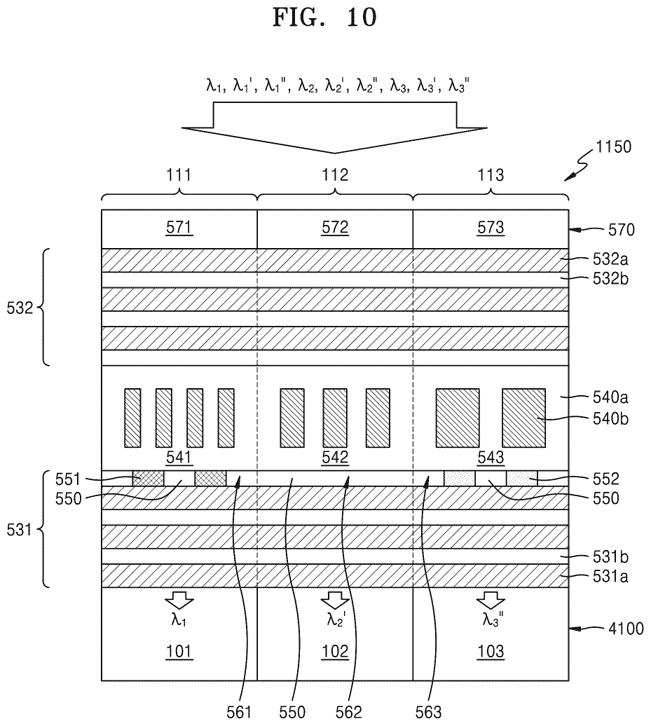

FIG. 10 is a cross-sectional view illustrating a spectral filter 1150 according to one or more embodiments. In FIG. 10, light within first, second, and third wavelength ranges is incident on the spectral filter 1150. Here, the first wavelength range includes wavelengths λ₁, λ₁′, and λ₁″, the second wavelength range includes wavelengths λ₂, λ₂′, and λ₂″, and the third wavelength range includes wavelengths λ₃, λ₃′, and λ₃″.

Referring to FIG. 10, the spectral filter 1150 may include the plurality of unit filters 111, 112, and 113 that are two-dimensionally arranged. Under this spectral filter 1150, the sensor substrate 4100 including the plurality of sensing elements 101, 102, and 103 respectively corresponding to the plurality of unit filters 111, 112, and 113 may be provided. In FIG. 10, three first, second, and third unit filters 111, 112, and 113 and three first, second, and third sensing elements 101, 102, and 103 are shown as an example, and different numbers of unit filters and sensing elements may be implemented.

The first unit filter 111 may have a central wavelength within the first wavelength range. The first wavelength range may have, for example, a wavelength range of blue light. However, this is only an example, and in addition to the above, the first wavelength range may have various wavelength ranges, depending on design conditions. The second unit filter 112 may have a central wavelength within the second wavelength range. The second wavelength range may be longer than the first wavelength range. The second wavelength range may have, for example, a wavelength range of green light, but is not limited thereto. The third unit filter 113 may have a central wavelength within the third wavelength range. The third wavelength range may be longer than the second wavelength range. The third wavelength range may have, for example, a wavelength range of red light, but is not limited thereto.

The first, second, and third unit filters 111, 112, and 113 may include a resonator and a bandpass filter 570 provided over that resonator. The resonator may include first and second reflective plates 531 and 532, which are spaced apart from each other. First, second, and third resonant layers 541, 542, and 543 may be provided between the first and second reflective plates 531 and 532 and respectively correspond to the first, second a third unit filters 111, 112 and 113. The bandpass filter 570 may include first, second, and third bandpass filters 571, 572, and 573 respectively corresponding to the first, second, and third resonant layers 541, 542, and 543.

The first unit filter 111 may include the first and second reflective plates 531 and 532, a first resonant layer 541 provided between the first and second reflective plates 531 and 532, and a first bandpass filter 571 provided over the first resonant layer 541. The second unit filter 112 may include the first and second reflective plates 531 and 532, a second resonant layer 542 provided between the first and second reflective plates 531 and 532, and a second bandpass filter 572 provided over the second resonant layer 542. The third unit filter 113 may include the first and second reflective plates 531 and 532, a third resonant layer 543 provided between the first and second reflective plates 531 and 532, and a third bandpass filter 573 provided over the third resonant layer 543.

Each of the first, second, and third bandpass filters 571, 572, and 573 may transmit only light of a particular wavelength range and block light of other wavelength ranges.

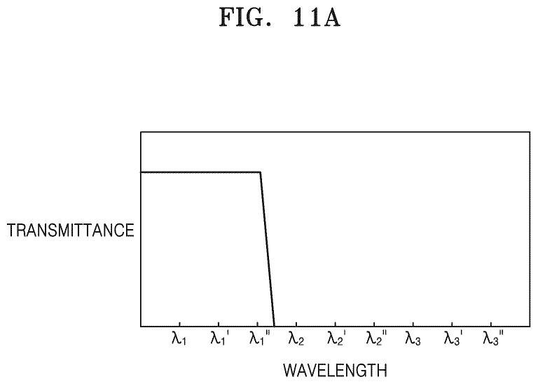

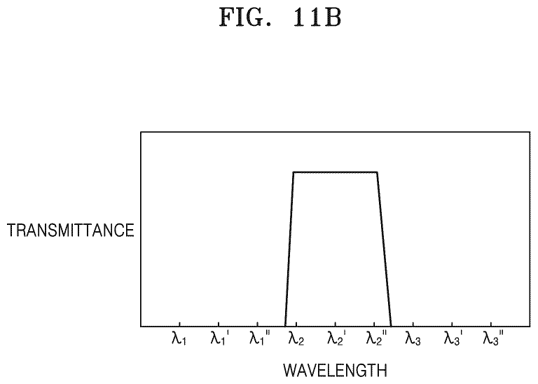

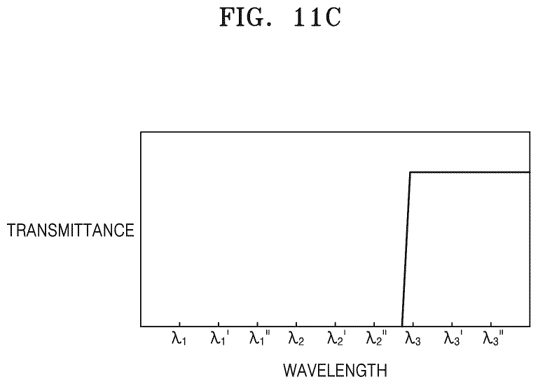

FIGS. 11A to 11C are graphs illustrating examples of transmission spectra of first, second, and third band-pass filters in the spectral filter shown in FIG. 10 according to one or more embodiments. In FIGS. 11A to 11C, transmission spectra of the first, second, and third bandpass filters 571, 572, and 573 are shown as an example. FIG. 11A shows the transmission spectrum of the first bandpass filter 571, and the first bandpass filter 571 may transmit only light of the first wavelength range (blue light wavelength range). FIG. 11B shows the transmission spectrum of the second bandpass filter 572, and the second bandpass filter 572 may transmit only light of the second wavelength range (green light wavelength range). In addition, FIG. 11C shows the transmission spectrum of the third bandpass filter 573, and the third bandpass filter 573 may transmit only light of the third wavelength range (red light wavelength range).

A color filter may be used for a bandpass filter 570. For example, the color filter may be commonly applied to a color display device such as a liquid crystal display device or an organic light-emitting display device. In this case, the first bandpass filter 571 may be a blue color filter, the second bandpass filter 572 may be a green color filter, and the third bandpass filter 573 may be a red color filter.

Each of the first, second, and third resonant layers 541, 542, and 543 may have a multi-mode resonance structure having a plurality of central wavelengths. In order to implement this multi-mode resonance structure, it may be necessary to form each of the first, second, and third resonant layers 541, 542, and 543 to have a certain thickness or thicker. For example, each of the first, second, and third resonant layers 541, 542, and 543 may have a thickness of about 200 nm to about 1,000 nm (e.g., about 250 nm to about 700 nm). However, the disclosure is not limited thereto.

The first, second, and third resonant layers 541, 542, and 543 may have different effective refractive indices so as to have different central wavelengths from each other. To this end, each of the first, second, and third resonant layers 541, 542, and 543 may include at least one material layer. In FIG. 10, each of the first, second, and third resonant layers 541, 542, and 543 includes a first material layer 540a and a second material layer 540b having different refractive indices. The second material layer 540b may be arranged inside the first material layer 540a to form a predefined pattern. Here, a size or shape of the pattern formed by the second material layer 540b may be changed to adjust an effective refractive index of each of the first, second, and third resonant layers 541, 542, and 543. The first, second, and third resonant layers 541, 542, and 543 may have the same thickness as each other. Each of the first and second material layers 540a and 540b may include, for example, silicon, silicon oxide, silicon nitride, titanium oxide, aluminum oxide, hafnium oxide, GaP, or the like. For example, the first material layer 540a may include silicon oxide, and the second material layer 540b may include titanium oxide having a higher refractive index than silicon oxide. The first, second, and third resonant layers 541, 542, and 543 may be formed to have the same thickness as each other.

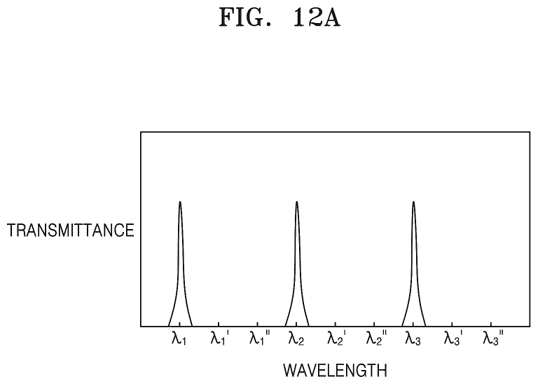

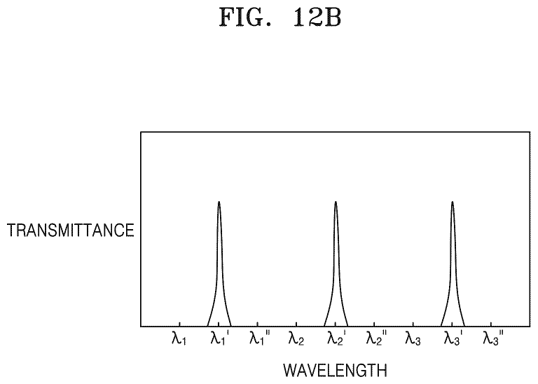

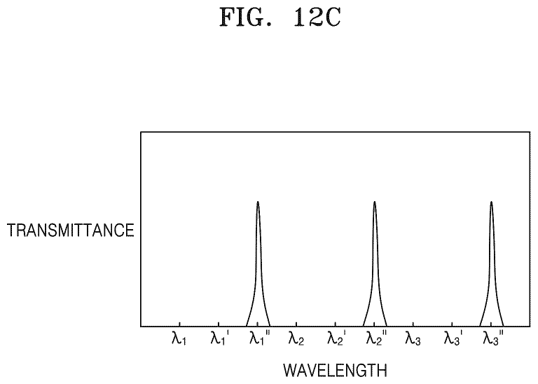

FIGS. 12A to 12C are graphs illustrating examples of transmission spectra of first, second, and third resonant layers in the spectral filter shown in FIG. 10 according to one or more embodiments. In FIGS. 12A to 12C, transmission spectra of the first, second, and third resonant layers 541, 542, and 543 are shown as an example. In FIGS. 12A to 12C, each of the first, second, and third resonant layers 541, 542, and 543 has three central wavelengths. However, the disclosure is not limited thereto, and each of the first, second, and third resonant layers 541, 542, and 543 may be configured to have two or four or more central wavelengths through adjustment of thickness and effective refractive index.

FIG. 12A shows the transmission spectrum of the first resonant layer 541, and the first resonant layer 541 may have first, second, and third wavelengths λ₁, λ₂, and λ₃ as central wavelengths thereof. Here, the wavelengths λ₁, λ₂, and λ₃ may be within the first, second, and third wavelength ranges, respectively. FIG. 12B shows the transmission spectrum of the second resonant layer 542, and the second resonant layer 542 may have wavelengths λ₁′, λ₂′, and λ₃′ as central wavelengths thereof. The wavelengths λ₁′, λ₂′, and λ₃′ may be positioned to be spaced apart from the first, second, and third wavelengths λ₁, λ₂, and λ₃, respectively, but are not necessarily limited thereto. Here, the wavelengths λ₁′, λ₂′, and λ₃′ may be within the first, second, and third wavelength ranges, respectively. FIG. 12C shows the transmission spectrum of the third resonant layer 543, and the third resonant layer 543 may have wavelengths λ₁″, λ₂″, and λ₃″ as central wavelengths thereof. The wavelengths λ₁″, λ₂″, and λ₃″ may be positioned to be spaced apart from the wavelengths λ₁′, λ₂′, and λ₃′, respectively, but are not necessarily limited thereto. Here, the wavelengths λ₁″, λ₂″, and λ₃″ may be within the first, second, and third wavelength ranges, respectively.

Referring to FIG. 10, the first and second reflective plates 531 and 532 are similar to the first and second reflective plates 131 and 132 shown in FIG. 4. The first reflective plate 531 may include the first DBR, and the second reflective plate 532 may include the second DBR. Each of the first and second DBRs may have a structure in which two or more dielectrics having different refractive indices from each other are alternately stacked. In FIG. 10, the first and second DBRs have a structure in which first material layers 531a and 532a and second material layer 531b and 532b having different indices from each other are alternately stacked, respectively. For example, the first material layers 531a and 532a may include silicon oxide, and the second material layer 531b and 532b may include titanium oxide having a higher refractive index than silicon oxide.

The first DBR may include first, second, and third reflective layers 561, 562, and 563 contacting the first, second, and third resonant layers 541, 542, and 543, respectively. For example, the first DBR of the first unit filter 111 may include the first reflective layer 561 contacting the first resonant layer 541, the first DBR of the second unit filter 112 may include the second reflective layer 562 contacting the second resonant layer 542, and the first DBR of the third unit filter 113 may include the third reflective layer 563 contacting the third resonant layer 543.

The first resonant layer 541 contacting the first resonant layer 541, the second reflective layer 562 contacting the second resonant layer 542, and the third reflective layer 563 contacting the third resonant layer 543 may have different effective refractive indices from each other. To this end, the first, second, and third reflective layers 561, 562, and 563 may include materials having different refractive indices from each other.

When the second resonant layer 542 has a central wavelength in the green light range, the second reflective layer 562 contacting that second resonant layer 542 may include the first material 550. The first material 550 may be, for example, one of materials included in the first DBR. When the first resonant layer 541 has a central wavelength in the blue light range, the first reflective layer 561 contacting that first resonant layer 541 may be configured to have an effective refractive index different from that of the second reflective layer 562. The first reflective layer 561 may include the first material 550 and a second material 551. When the first reflective layer 561 contacting the first resonant layer 541 has an effective refractive index different from that of the second reflective layer 562, reflectance in the blue light range may be improved. When the third resonant layer 543 has a central wavelength in the red light range, the third reflective layer 563 contacting that third resonant layer 543 may be configured to have an effective refractive index different from those of the first and second reflective layers 561 and 562. The third reflective layer 563 may include the first material 550 and a third material 552. When the third reflective layer 563 contacting the third resonant layer 543 has an effective refractive index different from those of the first and second reflective layers 561 and 562, reflectance in the red light range may be improved.

In the spectral filter 1150 shown in FIG. 10, when light in the first, second, and third wavelength ranges is incident on the bandpass filter 570, light of the wavelengths λ₁, λ₁′, and λ₁″ within the first wavelength range may pass through the first bandpass filter 571. In addition, light of the wavelengths λ₂, λ₂′, and λ₂″ within the second wavelength range may pass through the second bandpass filter 572, and light of the wavelengths λ₃, λ₃′, and λ₃″ within the third wavelength range may pass through the third bandpass filter 573.

When the light of the wavelengths λ₁, λ₁′, and λ₁″ passing through the first bandpass filter 571 is incident into the first resonant layer 541, only light of the wavelength λ₁ may be emitted from the first resonant layer 141 and incident on the first sensing element 101. When the light of the wavelengths λ₂, λ₂′, and λ₂″ passing through the second bandpass filter 572 is incident into the second resonant layer 542, only light of the wavelength λ₂′ may be emitted from the second resonant layer 142 and incident on the second sensing element 102. In addition, when the light of the wavelengths λ₃, λ₃′, and λ₃″ passing through the third bandpass filter 573 is incident into the third resonant layer 543, only light of the wavelength λ₃″ may be emitted from the third resonant layer 543 and incident on the third sensing element 103.

According to one or more embodiments, the bandpass filter 570 transmitting only light of a particular wavelength range is combined with the resonant layers 541, 542, and 543 of a multi-mode structure each having a plurality of central wavelengths, to implement the broadband spectral image sensor 1000 capable of detecting only light of a desired wavelength.

As shown in FIGS. 4, 7, 9 and 10, in embodiments where the reflective plate corresponding to the unit filter includes more than one material, the materials may be arranged in an alternating pattern. For example, in FIGS. 4, 7 and 9, the materials 151a and 151b are arranged in alternating patterns in unit filters 111 and 113. In FIG. 10, the materials 550 and 551 are arranged in an alternating pattern in unit filter 111, and the materials 550 and 552 are arranged in an alternating pattern in unit filter 113.

The spectral image sensor 1000 described above may be employed in various high-performance optical devices or high-performance electronic devices. These electronic devices may be, as non-limiting examples, smartphones, mobile phones, cell phones, personal digital assistants (PDAs), laptops, personal computers (PCs), various portable devices, home appliances, security cameras, medical cameras, automobiles, and the Internet of Things (IoT) devices, or other mobile or non-mobile computing devices.

In addition to the spectral image sensor 1000, the electronic device may further include a processor configured to control the spectral image sensor 1000, for example, an application processor (AP), and an operating system or an application program may be driven through the processor to control a plurality of hardware and software elements and perform various data processing and calculations. The processor may further include a graphics processing unit (GPU) and/or an image signal processor. When the processor includes an image signal processor, an image (or video) obtained by the spectral image sensor 1000 may be stored and/or output by using the processor.

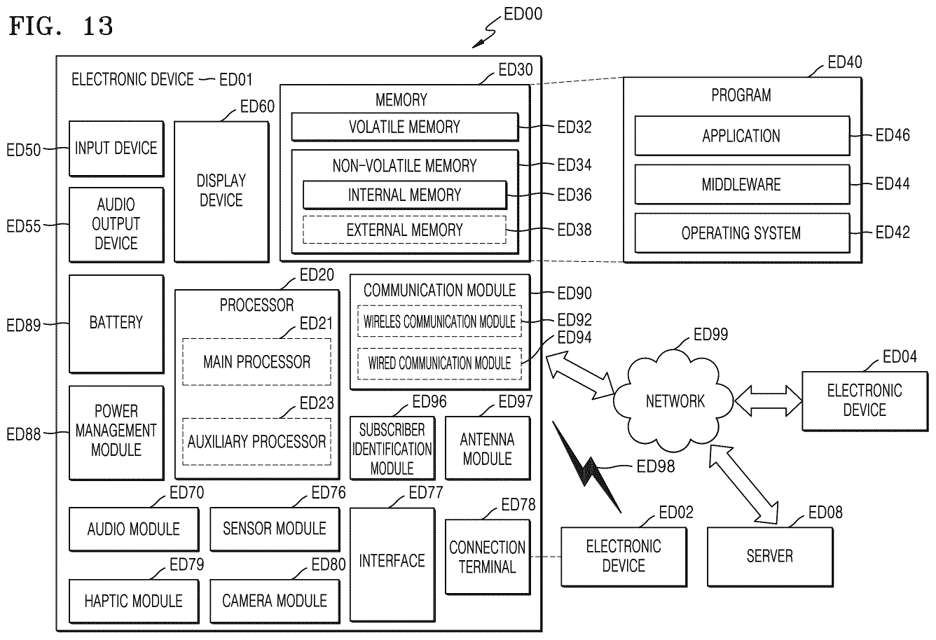

FIG. 13 is a block diagram illustrating an example of an electronic device according to one or more embodiments.

Referring to FIG. 13, in a network environment ED00, the electronic device ED01 may communicate with another electronic device ED02 through a first network ED98 (short-range wireless communication network or the like) or may communicate with another electronic device ED04 and/or a server ED08 through a second network ED99 (long-distance wireless communication network or the like). The electronic device ED01 may communicate with the electronic device ED04 through the server ED08. The electronic device ED01 may include a processor ED20, a memory ED30, an input device ED50, an audio output device ED55, a display device ED60, an audio module ED70, a sensor module ED76, an interface ED77, a haptic module ED79, a camera module ED80, a power management module ED88, a battery ED89, a communication module ED90, a subscriber identification module ED96, and/or an antenna module ED97. In the electronic device ED01, some of these elements (display device ED60 or the like) may be omitted or other elements may be added. Some of the elements may be implemented as a single integrated circuit. For example, the sensor module ED76 (fingerprint sensor, iris sensor, illumination sensor, or the like) may be implemented by being embedded in the display device ED60 (display or the like). In addition, in the spectral image sensor 1000, some functions (color sensor and illumination sensor) of the sensor module ED76 may be implemented in the spectral image sensor 1000 itself rather than in a separate sensor module.

The processor ED20 may execute software (program ED40 or the like) to control one or more other elements (hardware, software elements, or the like) in the electronic device ED01 connected to the processor ED20 and perform various data processing or calculations. As part of data processing or calculations, the processor ED20 may load commands and/or data received from other elements (sensor module ED76, communication module ED90, or the like) onto a volatile memory ED32, process the commands and/or data stored in the volatile memory ED32, and store resulting data in a non-volatile memory ED34. The processor ED20 may include a main processor ED21 (central processing unit, AP, etc.) and an auxiliary processor ED23 (GPU, image signal processor, sensor hub processor, communication processor, or the like) that may be operated independently of or together with the main processor ED21. The auxiliary processor ED23 may consume less power than the main processor ED21 and perform a specialized function.

The auxiliary processor ED23 may control functions and/or states associated with some elements (display device ED60, sensor module ED76, communication module ED90, or the like) from among the elements of the electronic device ED01, on behalf of the main processor ED21 while the main processor ED21 is in an inactive state (sleep state) or together with the main processor ED21 while the main processor ED21 is in an active state (application execution state). The auxiliary processor ED23 (image signal processor, communication processor, or the like) may be implemented as part of other functionally related elements (camera module ED80, communication module ED90, or the like).

The memory ED30 may store various data required by elements (processor ED20, sensor module ED76, or the like) of the electronic device ED01. For example, the data may include input data and/or output data for software (program ED40 or the like) and commands related thereto. The memory ED30 may include the volatile memory ED32 and/or the non-volatile memory ED34. The non-volatile memory ED34 may include an internal memory ED36 fixedly mounted within the electronic device ED01 and an external memory ED38 that is removable.

The program ED40 may be stored in the memory ED30 as software and may include an operating system ED42, middleware ED44, and/or an application ED46.

The input device ED50 may receive, from the outside (user or the like) of the electronic device ED01, commands and/or data to be used for an element (processor ED20 or the like) of the electronic device ED01. The input device ED50 may include a microphone, a mouse, a keyboard, and/or a digital pen (stylus pen or the like).

The audio output device ED55 may output an audio signal to the outside of the electronic device ED01. The audio output device ED55 may include a speaker and/or a receiver. The speaker may be used for general purposes such as multimedia playback or recording playback, and the receiver may be used to receive incoming calls. The receiver may be combined as part of the speaker or implemented as a separate, independent device.

The display device ED60 may visually provide information to the outside of the electronic device ED01. The display device ED60 may include a display, a hologram device, a projector, and a control circuit for controlling the device. The display device ED60 may include touch circuitry configured to detect a touch, and/or sensor circuitry (pressure sensor or the like) configured to measure intensity of force generated by the touch.

The audio module ED70 may convert sound into electrical signals or, conversely, convert electrical signals into sound. The audio module ED70 may obtain sound through the input device ED50 or may output sound through the audio output device ED55 and/or a speaker and/or headphone of another electronic device (electronic device ED02 or the like) that is directly or wirelessly connected to the electronic device ED01.

The sensor module ED76 may detect an operating state (power, temperature, or the like) of the electronic device ED01 or an external environment status (user status or the like) and generate electrical signals and/or data values corresponding to the detected status. The sensor module ED76 may include a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, and/or an illumination sensor.

The interface ED77 may support one or more designated protocols that may be used to directly or wirelessly connect the electronic device ED01 to another electronic device (electronic device ED02 or the like). The interface ED77 may include a high definition multimedia interface (HDMI), a universal serial bus (USB) interface, a secure digital (SD) card interface, and/or an audio interface.

A connection terminal ED78 may include a connector through which the electronic device ED01 may be physically connected to another electronic device (electronic device ED02 or the like). The connection terminal ED78 may include an HDMI connector, an USB connector, an SD card connector, and/or an audio connector (headphone connector or the like).

The haptic module ED79 may convert electrical signals into mechanical stimulation (vibration, motion, or the like) or electrical stimulation that the user may perceive through tactile or kinesthetic senses. The haptic module ED79 may include a motor, a piezoelectric element, and/or an electrical stimulation device.

The camera module ED80 may capture still images and moving images. The camera module ED80 may include a lens assembly including one or more lenses, the spectral image sensor 1000 of FIG. 1, image signal processors, and/or flashes. The lens assembly included in the camera module ED80 may collect light emitted from a subject to be image captured.

The power management module ED88 may manage power supplied to the electronic device ED01. The power management module ED88 may be implemented as part of a power management integrated circuit (PMIC).

The battery ED89 may supply power to elements of the electronic device ED01. The battery ED89 may include a non-rechargeable primary cell, a rechargeable secondary cell, and/or a fuel cell.

The communication module ED90 may support establishment of a direct (wired) communication channel and/or a wireless communication channel between the electronic device ED01 and another electronic device (electronic device ED02, electronic device ED04, server ED08, or the like), and communication performance through the established communication channel. The communication module ED90 may be operated independently of the processor ED20 (application processor or the like) and may include one or more communication processors that support direct communication and/or wireless communication. The communication module ED90 may include a wireless communication module ED92 (cellular communication module, short-range wireless communication module, global navigation satellite system (GNSS) communication module, or the like) and/or a wired communication module ED94 (local area network (LAN) communication module, power line communication module, or the like). From among these communication modules, the communication module may communicate with other electronic device through the first network ED98 (short-range communication network such as Bluetooth, WiFi Direct, or Infrared Data Association (IrDA)) or the second network ED99 (long-distance communication network such as cellular network, the Internet, or computer network (LAN, wide area network (WAN), or the like). These various types of communication modules may be integrated into a single element (single chip or the like) or may be implemented as a plurality of separate elements (a plurality of chips). The wireless communication module ED92 may identify and authenticate the electronic device ED01 in a communication network such as the first network ED98 and/or the subscriber identification module ED96 by using subscriber information (international mobile subscriber identity (IMSI) or the like) stored in the subscriber identification module ED96.

The antenna module ED97 may transmit signals and/or power to or receive signals and/or power from the outside (other electronic devices or the like). An antenna may include a radiator including a conductive pattern formed on a substrate (printed circuit board (PCB) or the like). The antenna module ED97 may include one or more antennas. When a plurality of antennas are included, an antenna suitable for a communication scheme used in a communication network such as the first network ED98 and/or the second network ED99 may be selected from among the plurality of antennas by the communication module ED90. Signals and/or power may be transmitted and received between the communication module ED90 and other electronic devices through the selected antenna. In addition to the antenna, other elements (radio-frequency integrated circuit (RFIC) or the like) may be included as part of the antenna module ED97.

Some of the elements may be connected to each other through communication schemes (bus, general purpose input and output (GPIO), serial peripheral interface (SPI), mobile industry processor interface (MIPI), or the like) between peripheral devices and may exchange signals (commands, data, or the like) with each other.

Commands or data may be transmitted or received between the electronic device ED01 and the external electronic device ED04 through the server ED08 connected to the second network ED99. The other electronic devices ED02 and ED04 may be the same type of devices as the electronic device ED01 or may be of a type different from that of the electronic device ED01. All or some of operations executed in the electronic device ED01 may be executed in one or more electronic devices from among the other electronic devices ED02 and ED04. For example, when the electronic device ED01 needs to perform a certain function or service, the electronic device ED01 may request one or more other electronic devices to perform some or all of the function or service, instead of executing the function or service itself. The one or more other electronic devices receiving the request may execute an additional function or service related to the request and transfer a result of the execution to the electronic device ED01. To this end, cloud computing, distributed computing, and/or client-server computing technologies may be used.

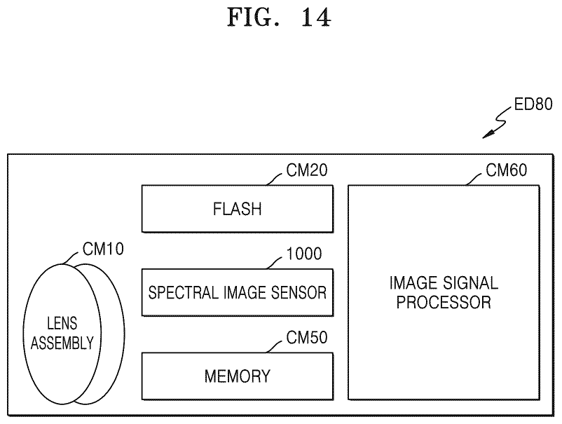

FIG. 14 is a block diagram illustrating an example of a camera module ED80 of FIG. 13 according to one or more embodiments.

Referring to FIG. 14, the camera module ED80 may include a lens assembly CM10, a flash CM20, the spectral image sensor 1000 (spectral image sensor 1000 of FIG. 2 or the like), a memory CM50 (buffer memory or the like), and/or an image signal processor CM60. The lens assembly CM10 may collect light emitted from a subject to be image captured. The camera module ED80 may include a plurality of lens assemblies CM10, and in this case, the camera module ED80 may be a dual camera, a 360-degree camera, or a spherical camera. Some of the plurality of lens assemblies CM10 may have the same lens properties (angle of view, focal length, autofocus, F number, optical zoom, or the like) or may have different lens properties from each other. The lens assembly CM10] may include a wide-angle lens or a telephoto lens.

The flash CM20 may emit light that is used to enhance light emitted or reflected from the subject. The flash CM20 may include one or more light-emitting diodes (LEDs) (red-green-blue (RGB) LED, white LED, infrared LED, ultraviolet LED, or the like) and/or a xenon lamp. The spectral image sensor 1000 may be the spectral image sensor described with reference to FIG. 2 and may convert light emitted or reflected from the subject and transferred through the lens assembly CM10 to obtain an image corresponding to the subject. The spectral image sensor 1000 may include one or more sensors selected from among image sensors having different properties from each other, such as a RGB sensor or a black and white (BW) sensor. Each of the sensors included in the spectral image sensor 1000 may be implemented as a CCD sensor and/or a CMOS sensor.

The memory CM50 may store part or all of data of an image obtained through the spectral image sensor 1000 for a next image processing task. For example, when a plurality of images are obtained at high speed, the obtained original data (Bayer-Patterned data, high-resolution data, or the like) is stored in the memory CM50, only low-resolution images are displayed, and then, original data of a selected image (user selection or the like) may be transferred to the image signal processor CM60. The memory CM50 may be integrated into the memory ED30 of the electronic device ED01 or may be configured as a separate memory that operates independently.

The image signal processor CM60 may perform image processing on images obtained through the spectral image sensor 1000 or image data stored in the memory CM50. Image processing may include depth map creation, three-dimensional modeling, panorama creation, feature point extraction, image synthesis, and/or image compensation (noise reduction, resolution adjustment, brightness adjustment, blurring, sharpening, softening, or the like). The image signal processor CM60 may perform control (exposure time control, read-out timing control, or the like) on elements (spectral image sensor 1000 or the like) included in the camera module ED80. An image processed by the image signal processor CM60 may be stored back in the memory CM50 for further processing or provided to external elements (memory ED30, display device ED60, electronic device ED02, electronic device ED04, server ED08, or the like) of the camera module ED80. The image signal processor CM60 may be integrated into the processor ED20 or may be configured as a separate processor that operates independently of the processor ED20. When the image signal processor CM60 is configured as a separate processor from the processor ED20, the image processed by the image signal processor CM60 may undergo additional image processing by the processor ED20 and then may be displayed through the display device ED60.

The electronic device ED01 may include a plurality of camera modules ED80 having different properties or functions from each other. In this case, one of the plurality of camera modules ED80 may be a wide-angle camera, and the other one may be a telephoto camera. Similarly, one of the plurality of camera modules ED80 may be a front camera, and the other one may be a rear camera.

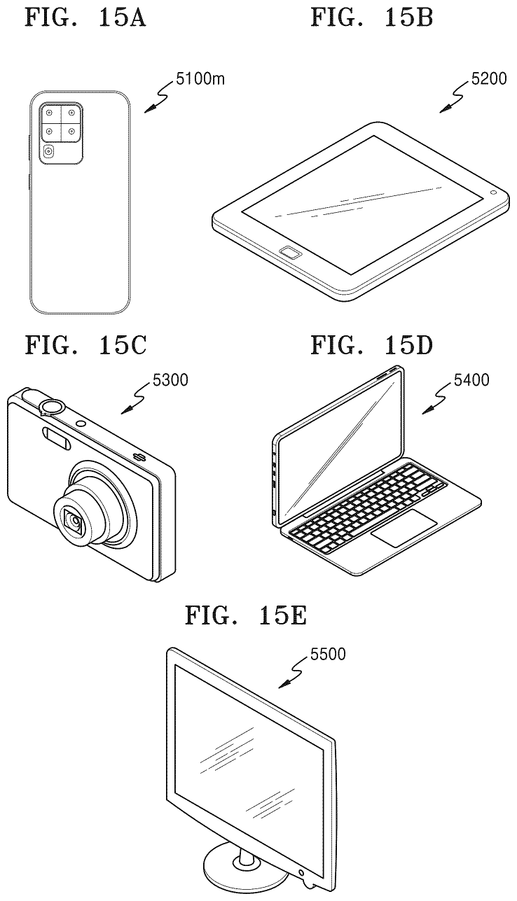

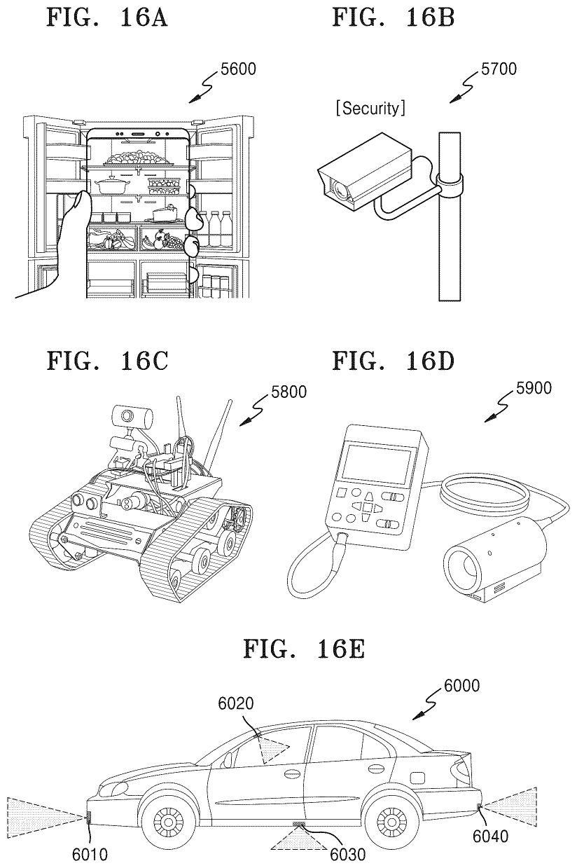

FIGS. 15A to 16E are diagrams illustrating various examples of an electronic device according to one or more embodiments. The spectral image sensor 1000 according to one or more embodiments may be applied to a mobile phone or smartphone 5100m shown in FIG. 15A a tablet or smart tablet 5200 shown in FIG. 15B, a digital camera or camcorder 5300 shown in FIG. 15C, a laptop computer 5400 shown in FIG. 15D, or a television or smart television 5500 shown in FIG. 15E. For example, the smartphone 5100m or the smart tablet 5200 may include a plurality of high-resolution cameras each equipped with a high-resolution spectral image sensor. By using high-resolution cameras, depth information of subjects in an image may be extracted, outfocusing of an image may be adjusted, or the subjects in the image may be automatically identified.

In addition, the spectral image sensor 1000 may be applied to a smart refrigerator 5600 shown in FIG. 16A, a security camera 5700 shown in FIG. 16B, a robot 5800 shown in FIG. 16C, a medical camera 5900 shown in FIG. 16D, or the like. For example, the smart refrigerator 5600 may automatically recognize food in the refrigerator by using a spectral image sensor and inform the user the presence of certain food, a type of food received or shipped, or the like through a smartphone. The security camera 5700 may provide ultra-high resolution images and, by using high sensitivity, have objects or people in the image be recognizable even in a dark environment. The robot 5800 may provide high-resolution images when deployed at disaster or industrial sites that cannot directly accessed by humans. The medical camera 5900 may provide high-resolution images for diagnosis or surgery and may dynamically adjust a field of view thereof.

In addition, the spectral image sensor 1000 may be applied to a vehicle 6000, as shown in FIG. 16E. The vehicle 6000 may include a plurality of vehicle cameras 6010, 6020, 6030, and 6040 at various positions, and each of the vehicle cameras 6010, 6020, 6030, and 6040 may include a spectral image sensor according to an embodiment. The vehicle 6000 may provide the driver with various information about the inside or surroundings of the vehicle 6000 by using the plurality of vehicle cameras 6010, 6020, 6030, and 6040, and automatically recognize objects or people in an image and provide information necessary for autonomous driving.

According to one or more embodiments, in a DBR of a unit filter having a central wavelength within a blue light wavelength range, a reflective layer in contact with a resonant layer includes a second material having a refractive index different from that of a first material, thereby improving reflectance in the blue light wavelength range. In addition, in a DBR of a unit filter having a central wavelength within a red light wavelength range (or, infrared range), a reflective layer contacting a resonant layer includes a first material and a third material having a refractive index different from that of the first material, thereby improving reflectance in the red light wavelength range (or, infrared range). Accordingly, a spectral image sensor with improved spectral performance may be implemented.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A spectral image sensor comprising:
a sensor substrate comprising a plurality of sensing elements; and
a spectral filter provided on the sensor substrate, the spectral filter comprising a first unit filter configured to transmit light of a first central wavelength and a second unit filter configured to transmit light of a second central wavelength that is different from the first central wavelength,
wherein the first unit filter and the second unit filter comprise:
a first reflective plate comprising a first distributed Bragg reflector (DBR);
a second reflective plate spaced apart from the first reflective plate; and
wherein the first unit filter comprises a first resonant layer between the first reflective plate and the second reflective plate,
wherein the second unit filter comprises a second resonant layer between the first reflective plate and the second reflective plate,
wherein the first DBR comprises a first reflective layer contacting the first resonant layer and having a first effective refractive index, and
wherein the first DBR comprises a second reflective layer contacting the second resonant layer and having a second effective refractive index that is different from the first effective refractive index.

2. The spectral image sensor of claim 1, wherein the first resonant layer is configured to have a central wavelength within a green light wavelength range, and
wherein the second resonant layer is configured to have a central wavelength within a red light wavelength range.

3. The spectral image sensor of claim 1, wherein the first resonant layer is configured to have a central wavelength within a green light wavelength range, and
wherein the second resonant layer is configured to have a central wavelength within a blue light wavelength range.

4. The spectral image sensor of claim 1, wherein the first reflective layer comprises a first material, and
wherein the second reflective layer comprises the first material and a second material arranged in an alternating pattern, the second material having a refractive index that is different from a refractive index of the first material.

5. The spectral image sensor of claim 4, wherein the first material comprises titanium dioxide (TiO₂), and
wherein the second material comprises silicon dioxide (SiO₂).

6. The spectral image sensor of claim 4, wherein the first material comprises titanium dioxide (TiO₂), and
wherein the second material comprises silicon (Si).

7. The spectral image sensor of claim 1, wherein the first reflective layer comprises a first material, and
wherein the second reflective layer comprises a second material having a refractive index that is different from a refractive index of the first material.

8. The spectral image sensor of claim 1, wherein the second reflective plate comprises a second DBR.

9. The spectral image sensor of claim 8, wherein the second DBR comprises a third reflective layer contacting the first resonant layer and a fourth reflective layer contacting the second resonant layer, and
wherein the fourth reflective layer has a fourth effective refractive index that is different from a third effective refractive index of the third reflective layer.

10. The spectral image sensor of claim 1, wherein the second reflective plate comprises a metal reflective plate.

11. The spectral image sensor of claim 10, wherein the metal reflective plate comprises aluminum (Al), copper (Cu), silver (Ag), gold (Au), titanium (Ti), tungsten (W), or titanium nitride (TiN).

12. The spectral image sensor of claim 1, wherein the first resonant layer has an effective refractive index that is different from a refractive index of the second resonant layer.

13. The spectral image sensor of claim 12, wherein a thickness of the first resonant layer is substantially the same as a thickness of the second resonant layer.

14. The spectral image sensor of claim 1, wherein the first unit filter comprises a first bandpass filter corresponding to the first resonant layer, and
wherein the second unit filter comprises a second bandpass filter corresponding to the second resonant layer.

15. The spectral image sensor of claim 14, wherein the first bandpass filter is configured to transmit light of a first wavelength range, and
wherein the second bandpass filter is configured to transmit light of a second wavelength range.

16. The spectral image sensor of claim 15, wherein the first central wavelength is within the first wavelength range, and
wherein the second resonant layer is configured to have a central wavelength within the second wavelength range.

17. The spectral image sensor of claim 1, wherein each of the plurality of sensing elements comprises:
a wiring layer comprising a driving circuit; and
a photodiode on the wiring layer.

18. The spectral image sensor of claim 1, further comprising a timing controller, a row decoder, and an output circuit.

19. An electronic device, comprising:
a spectral image sensor, comprising:
a sensor substrate comprising a plurality of sensing elements; and
a spectral filter provided on the sensor substrate, the spectral filter comprising a first unit filter configured to transmit light of a first central wavelength and a second unit filter configured to transmit light of a second central wavelength that is different from the first central wavelength,
wherein the first unit filter and the second unit filter comprise:
a first reflective plate comprising a first distributed Bragg reflector (DBR);
a second reflective plate spaced apart from the first reflective plate; and
wherein the first unit filter comprises a first resonant layer between the first reflective plate and the second reflective plate,
wherein the second unit filter comprises a second resonant layer between the first reflective plate and the second reflective plate,
wherein the first DBR comprises a first reflective layer contacting the first resonant layer and having a first effective refractive index, and
wherein the first DBR comprises a second reflective layer contacting the second resonant layer and having a second effective refractive index that is different from the first effective refractive index.

20. The electronic device of claim 19, wherein the electronic device comprises a mobile phone, a smartphone, a tablet, a smart tablet, a digital camera, a camcorder, a laptop computer, a television, a smart television, a smart refrigerator, a security camera, a robot, or a medical camera.
